(19) United States
(12) Patent Application Publication
(10) Pub. No.: US 2008/0122023 A1
(43) Pub. Date: May 29, 2008

(54) METHOD OF MANUFACTURING CMOS IMAGE SENSOR

(76) Inventor: Sang-Gi Lee, Gyeonggi-do (KR)

Correspondence Address: SHERR & NOURSE, PLLC, 620 HERNDON PARKWAY, SUITE 200, HERNDON, VA, 20170, US

(21) Appl. No.: 11/935,257

(22) Filed: Nov. 5, 2007

(30) Foreign Application Priority Data
Nov. 29, 2006 (KR) 10-2006-0118978

(51) Int. Cl. H01L 31/0216; H01L 21/00

(52) U.S. Cl. 257/443; 438/703; 257/E21.001; 257/E31.12

(57) ABSTRACT

An image sensor and a method of manufacturing a CMOS image sensor in which a high-temperature annealing is conducted without causing cracking in a passivation layer. The method may include forming a first passivation insulating layer on and/or over a semiconductor substrate including a metal pad and a plurality of metal wirings; performing a sintering process on the first passivation insulating layer in a hydrogen atmosphere; forming a second passivation insulating layer on and/or over the first passivation insulating layer; and performing an etching process using a photoresist pattern on the second passivation insulating layer to expose the uppermost surface of the metal pad.

The present application claims priority under 35 U.S.C. 119 to Korean Patent Application No. 10-2006-0118978 (filed on Nov. 29, 2006), which is hereby incorporated by reference in its entirety.

### BACKGROUND

An image sensor is a semiconductor device used to convert optical images detected by the image sensor to electric signals. Image sensors may be classified as a charge coupled device (CCD) and a complementary metal oxide semiconductor (CMOS).

A CCD image sensor is provided with metal oxide silicon (MOS) capacitors that are spatially positioned within close proximity to each other and charge carriers are stored in and transferred to the capacitors. A CMOS image sensor may be provided with a plurality of MOS transistors corresponding to pixels of a semiconductor device having a control circuit and a signal processing circuit as peripheral circuits. The control circuit and the signal processing unit may be integrated together to employ a switching method that detects output through the MOS transistors.

The CCD image sensor provides excellent qualities in terms of photosensitivity and noise, but however, is not suitable for high integration and low power consumption. On the other hand, the CMOS image sensor is simple to manufacture and is suitable for high integration and provides low power consumption.

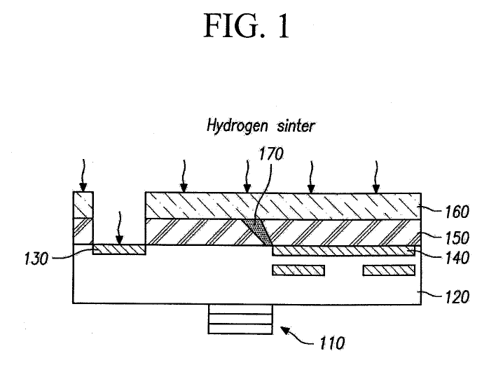

As illustrated in example FIG. 1, a CMOS image sensor may include semiconductor substrate 120 including metal pad 130 and a plurality of metal wirings 140. Passivation oxide layer 150 and passivation nitride layer 160 may be sequentially deposited on and/or over semiconductor substrate 120. A planarization process on passivation oxide layer 150 may be conducted using chemical mechanical polishing (CMP). Also, a photoelectric conversion part, etc., such as photodiode 110 formed of red light, green light, and blue light can be provided at the lowermost region of semiconductor substrate 120.

A photoresist layer may be formed and patterned on and/or over passivation nitride layer 160. An etching may be performed on passivation oxide layer 150 and passivation nitride layer 160 using the patterned photoresist layer to expose the uppermost surface of metal pad 130.

When the uppermost surface of metal pad 130 is exposed, a sintering process may be performed using hydrogen at a temperature of approximately 400° C., producing crack 170 in a region of passivation oxide layer 150. Crack 170 results from when a sintering process is performed in a stage where an etching process is performed on passivation nitride layer 150 and passivation nitride layer 160. This results in increased stresses at the interface between passivation oxide layer 150 and passivation nitride layer 160. Such stresses may be transferred to metal wirings 140 formed in semiconductor substrate 120 which in turn results in crack 170 due to the volume expansion of metal wirings 140. Consequently, the reliability of metal wiring 140 is deteriorated. Moreover, since a sintering process cannot be performed at a temperature of greater than 400° C., it is difficult to improve the image characteristics.

### SUMMARY

Embodiments relate to a method of manufacturing a CMOS image sensor capable of performing a high-temperature annealing without causing cracking in a passivation oxide layer.

Embodiments relate to a method of manufacturing a CMOS image sensor including at least one of the following steps. Providing a semiconductor substrate including a metal pad and a plurality of metal wirings. Forming a first passivation insulating layer over the semiconductor substrate. Performing a sintering process on the first passivation insulating layer in a hydrogen atmosphere. Forming a second passivation insulating layer over the first passivation insulating layer. And then performing an etching process using a photoresist pattern on the second passivation insulating layer to expose the uppermost surface of the metal pad.

Embodiments relate to a CMOS image sensor including a semiconductor substrate including a metal pad and a plurality of metal wirings; a first passivation insulating layer formed over the semiconductor substrate; a second passivation insulating layer formed over the first passivation insulating layer; a photoresist formed over the second passivation insulating layer; and a plurality of photodiodes formed on the lowermost region of the semiconductor substrate. In accordance with embodiments, a sintering process is performed on the first passivation insulating layer in a hydrogen atmosphere prior to the second passivation layer being formed over the first passivation insulating layer.

### DRAWINGS

Example FIG. 1 illustrates a CMOS image sensor.

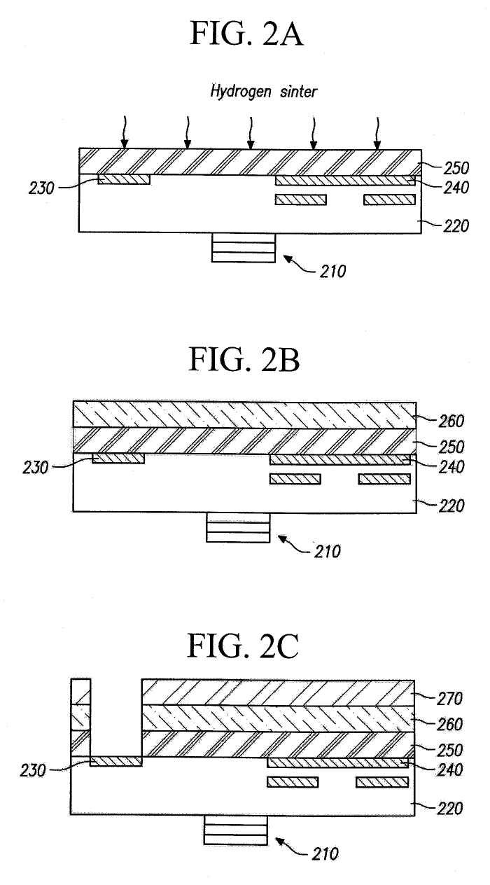

Example FIGS. 2A to 2C illustrate a CMOS image sensor, in accordance with embodiments.

### DESCRIPTION

As illustrated in example FIG. 2A, first passivation insulating layer 250 can be formed on and/or over semiconductor substrate 220 formed of P-type episilicon including metal pad 230 and a plurality of metal wirings 240 for making a wire bonding. Laterally wide metal wirings 240 may be used in order to block light flowing into the peripheral region of the CMOS image sensor. First passivation insulating layer 250 may be composed of an oxide material such as SiOₓ. A plurality of photoelectric conversion parts, etc., such as photodiode 210 formed of red light, green light, and blue light can be provided on the lowermost region of semiconductor substrate 220.

As illustrated in example FIG. 2B, instead of conducting an annealing process, a chemical mechanical polishing (CMP) process can be performed on first passivation insulating layer 250. Thereafter, a high-temperature annealing process such as a hydrogen sintering process, can be performed on the planarized first passivation insulating layer 250 in a hydrogen atmosphere. At this time, considering the image characteristics, the hydrogen sintering process can be performed to be freely modified at a high-temperature of between approximately 400 to 450° C. for between approximately ten to thirty minutes.

Second passivation insulating layer 260 can then be formed on and/or over first passivation insulating layer 250 on which the hydrogen sintering process is performed. Second passivation insulating layer 260 can be composed of a nitride-based material such as SiₓNₓ.

After first passivation insulating layer 250 is formed, the hydrogen sintering process can be immediately performed thereon prior to performing an etching process. Accordingly, the stress due to heat can be eliminated when second passivation insulating layer 260 is formed on and/or over first passivation insulating layer 250. Thereby, the volume expansion of the metal wirings can be reduced, making it possible to prevent a cracking phenomenon.

As illustrated in example FIG. 2C, photoresist 270 can be formed on and/or over second passivation insulating layer 260. Photoresist 270 can be patterned in order to expose the uppermost surface of metal pad 230 region. First passivation insulating layer 250 and second passivation insulating layer 260 can be etched using the patterned photoresist 270 as an etching mask to expose the uppermost surface of metal pad 230 in order to form a wire bonding.

In accordance with embodiments, a process of forming a CMOS image sensor can relieve the stresses occurring between first passivation insulating layer 250 and second passivation insulating layer 260. This in turn, can prevent cracking of the oxide in a high-temperature hydrogen sintering process, and thus, enhances the reliability of the metal wirings. Because the process permits a sintering process even at a high-temperature, i.e., those greater than 400° C., it is possible to enhance the image characteristics of the semiconductor device.

In accordance with embodiments, a hydrogen sintering process can be performed before etching the passivation insulating layer in a process exposing the uppermost surface of the metal pad in order to make a wire bonding. This makes it possible to prevent the passivation insulating layer from cracking. Suppression of cracking in the first passivation insulating layer can also facilitate high-temperature sintering processing, which enhances image characteristics.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
providing a semiconductor substrate including a metal pad and a plurality of metal wirings;
forming a first passivation insulating layer over the semiconductor substrate;
performing a sintering process on the first passivation insulating layer in a hydrogen atmosphere;
forming a second passivation insulating layer over the first passivation insulating layer; and then
performing an etching process using a photoresist pattern on the second passivation insulating layer to expose the uppermost surface of the metal pad.

2. The method of claim 1, further comprising planarizing the uppermost surface of the first passivation insulating layer by performing a chemical mechanical polishing process after forming the first passivation insulating layer.

3. The method of claim 1, wherein the first passivation insulating layer comprises an oxide-based material.

4. The method of claim 3, wherein the oxide-based material comprises SiOₓ.

5. The method of claim 1, wherein the second passivation insulating layer comprises a nitride-based material.

6. The method of claim 5, wherein the nitride-based material comprises SiₓNₓ.

7. The method of claim 1, wherein performing the sintering process includes performing a high-temperature annealing process.

8. The method of claim 7, wherein the high-temperature annealing process is conducted at a temperature of between approximately 400 to 450° C.

9. The method of claim 8, wherein the high-temperature annealing process is conducted for approximately ten to thirty minutes.

10. The method of claim 1, wherein the semiconductor substrate comprises a P-type episilicon material.

11. The method of claim 1, wherein the metal wirings are sized to block light flowing into a peripheral region of the semiconductor substrate.

12. The method of claim 1, further comprising providing a plurality of photodiodes on the lowermost region of the semiconductor substrate.

13. An apparatus comprising:
a semiconductor substrate including a metal pad and a plurality of metal wirings;
a first passivation insulating layer formed over the semiconductor substrate;
a second passivation insulating layer formed over the first passivation insulating layer;
a photoresist formed over the second passivation insulating layer; and
a plurality of photodiodes formed on the lowermost region of the semiconductor substrate,
wherein a sintering process is performed on the first passivation insulating layer in a hydrogen atmosphere prior to the second passivation layer being formed over the first passivation insulating layer.

14. The apparatus of claim 13, wherein the first passivation insulating layer comprises SiO₂.

15. The apparatus of claim 13, wherein the uppermost surface of the first passivation insulating layer is planarized using a chemical mechanical polishing process.

16. The apparatus of claim 13, wherein the sintering process is conducted at a temperature of between approximately 400 to 450° C. for between approximately ten to thirty minutes.

17. The apparatus of claim 13, wherein the photoresist is patterned and then the first passivation insulating layer and the second passivation insulating layer are etched using the patterned photoresist as an etching mask to expose the uppermost surface of metal pad.

18. The apparatus of claim 13, wherein the first passivation insulating layer comprises SiOₓ, the second passivation insulating layer comprises SiₓNₓ, and the semiconductor substrate comprises a P-type episilicon material.

19. The apparatus of claim 13, wherein the metal wirings are sized to block light flowing into a peripheral region of the semiconductor substrate.
